(19) United States
(12) Patent Application Publication
(10) Pub. No.: US 2023/0022174 A1
(43) Pub. Date: Jan. 26, 2023

(54) SUBSTRATE TRANSFER SYSTEM WITH LAMP HEATER, CHAMBER PURGE METHOD

(71) Applicant: ASM IP Holding, B.V., Almere (NL)

(72) Inventors: Wataru Kobayashi, Sagamihara-shi (JP); Masaei Suwada, Nagaoka-shi (JP)

(21) Appl. No.: 17/813,960

(22) Filed: Jul. 21, 2022

Related U.S. Application Data
(60) Provisional application No. 63/225,323, filed on Jul. 23, 2021.

(51) Int. Cl. H01L 21/67; C23C 14/54; H01L 21/687

(52) U.S. Cl. CPC H01L 21/67115; C23C 14/541; H01L 21/68764

(57) ABSTRACT

Examples of a substrate transfer system include a chamber in which a plurality of through holes are formed on a side surface, a substrate transfer device provided in the chamber, and a lamp heater disposed in the chamber. The lamp heater is configured to heat an inner wall of the chamber and the substrate transfer device.

### FIELD

Examples are described which relate to a substrate transfer system and a chamber purge method using the substrate transfer system.

### BACKGROUND

Heating element such as a lamp heater is used, for example, in a thermal process of forming a film on a substrate surface. For example, in a film forming process by thermal CVD, a film is deposited by thermally decomposing a raw material gas on a substrate heated by the heating element. A transfer chamber for transferring a substrate may be provided separately from a reactor chamber (RC), which is a chamber for performing a process such as film formation, etching, or film modification. It is necessary to efficiently remove water molecules adhering to the inner wall of this transfer chamber.

### SUMMARY

Some examples described herein may address the above-described problems. Some examples described herein may provide a substrate transfer system and a chamber purge method capable of efficiently removing moisture adhering to an inner wall of a transfer chamber.

In some examples, a substrate transfer system includes a chamber in which a plurality of through holes are formed on a side surface, a substrate transfer device provided in the chamber, and a lamp heater disposed in the chamber.

### BRIEF DESCRIPTION OF THE DRAWINGS

FIG. 1 is a diagram illustrating a configuration example of a substrate transfer system;

FIG. 2 is a diagram showing an example of a method of fixing a flange to a lamp heater;

FIG. 3 is a diagram showing a method of attaching the lamp heater to a chamber;

FIG. 4 is a cross-sectional view of the chamber and light emitting portions;

FIG. 5 shows a spread of light by broken lines;

FIG. 6 shows an example of the light emitting portion;

FIG. 7 is a diagram showing an example of a substrate processing apparatus;

FIG. 8A shows a bottom view of a lid;

FIG. 8B is a cross-sectional view of a portion of the lid;

FIG. 8C is a cross-sectional view of a portion of the lid;

FIG. 9 is a diagram showing an example of providing lamp heaters on an inner wall lower surface of the chamber;

FIG. 10 shows the lamp heaters attached to the substrate transfer device;

FIG. 11 shows a plate-like body in which a lamp heater is housed; and

FIG. 12 is a diagram showing a configuration example of the plate-like body.

### DETAILED DESCRIPTION

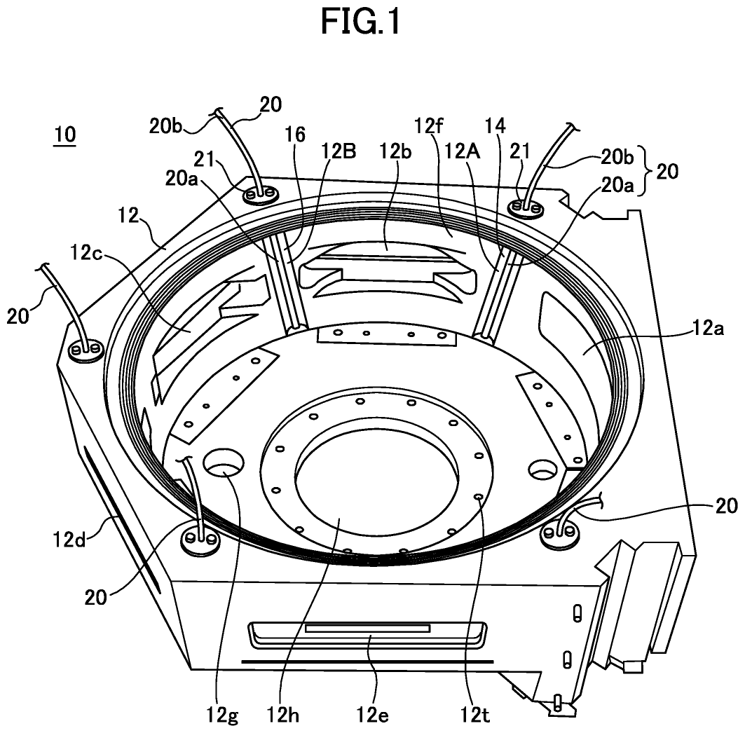

A substrate transfer system and a chamber purge method will be described with reference to FIGS. 1 to 12. The same or corresponding components are denoted by the same reference numerals, and a repetition of the description may be omitted.

### Embodiment

FIG. 1 is a diagram illustrating a configuration example of a substrate transfer system 10. More specifically, FIG. 1 is a diagram showing primarily a chamber 12, a lamp heater 20 attached to the chamber 12. According to one example, the chamber 12 is provided as a Wafer Handling Chamber (WHC). A plurality of through holes are formed in a side surface of the chamber 12. In the example of FIG. 1, through holes 12a, 12b, 12c, 12d, 12e are formed in the side surface of the chamber 12.

According to one example, a substrate transfer device provided in the chamber 12 carries a substrate into an adjacent chamber or carries the substrate from the adjacent chamber into the chamber 12. During its carry-out and carry-in, the substrate passes through at least one of the through holes 12a, 12b, 12c, 12d, 12e.

According to one example, the substrate transfer device may be secured to the chamber 12 by being screwed into screw holes 12t while closing a device mounting hole 12h on a lower surface of the chamber 12.

In FIG. 1, concave parts 12A, 12B formed on an inner wall of the chamber 12 are illustrated. According to one example, the concave parts 12A, 12B are longitudinally or vertically extending grooves provided on an inner wall side surface of the chamber 12. The concave parts 12A, 12B are provided for housing light emitting portions 20a of the lamp heaters 20, respectively. Each of the lamp heaters 20 includes the light emitting portion 20a, and a power supply cord 20b for supplying power to the light emitting portion 20a. The lamp heaters 20 are, for example, halogen heaters. According to another example, the lamp heaters 20 are any kind of IR lamps. The lamp heaters 20 may be replaced with inductive heaters or resistive heating elements.

According to one example, the lamp heater 20 is fixed to a flange 21. By fixing the flange 21 integrated with the lamp heater 20 to the chamber 12, the light emitting portion 20a is stably held in the concave part 12A.

Reflecting surfaces 14, 16 are formed on the concave parts 12A, 12B respectively.

In other words, a wall surface of the concave part 12A is the reflecting surface 14, and a wall surface of the concave part 12B is the reflecting surface 16. The reflecting surfaces 14, 16 are formed for reflecting light. According to one example, the reflecting surfaces 14, 16 are formed by mirror-finishing the concave parts 12A, 12B. According to another example, the reflecting surfaces 14, 16 are coatings or reflective sheets. According to one example, the reflecting surfaces 14, 16 may respectively be formed over the entire surfaces of the concave parts 12A, 12B.

Light of the light emitting portion 20a housed in the concave part 12A is widely irradiated to the inner wall of the chamber 12 by being reflected by the reflecting surface 14. Light of the light emitting portion 20a housed in the concave part 12B is widely irradiated to the inner wall of the chamber 12 by being reflected by the reflecting surface 16. Thus, radiant heat generated from the lamp heaters 20 is directed toward the inner wall of the chamber 12.

According to one example, the concave parts and the light emitting portions 20a are provided at substantially equal intervals along the inner wall side surface of the chamber 12.

That is, the lamp heaters 20 are provided at substantially equal intervals in a plan view. In the example of FIG. 1, five lamp heaters 20 and five concave parts are provided. In this example, one concave part houses one lamp heater 20. According to another example, one concave part may house at least two lamp heaters 20. According to still another example, number of concave parts is not limited to five.

By providing the lamp heater 20 in the concave part, the lamp heater 20 does not protrude into a wafer handling region of the chamber 12. Therefore, a movable region of the substrate transfer device in the chamber 12 is not limited by the presence of the lamp heater 20. In the example of FIG. 1, one concave part and one lamp heater 20 are provided between the two adjacent through holes of the side surface of the chamber 12. According to another example, two or more concave parts and two or more lamp heaters may be provided between the adjacent two through holes.

According to one example, an exhaust port 12g is provided in the lower surface of the chamber 12. The gas in the chamber 12 is exhausted through the exhaust port 12g at all times or periodically. In FIG. 1, an upper surface of the chamber 12 is opened by an upper opening 12f. The upper opening 12f is covered for example by a lid. According to one example, an interior of the chamber 12 is a vacuum in an industrial sense. In a vacuum state, the substrate is transferred from an inside of the chamber 12 to an outside, and the substrate is transferred from the outside of the chamber 12 to the inside. In that case, a vacuum pump is connected to the exhaust port 12g to increase the degree of vacuum in the chamber 12.

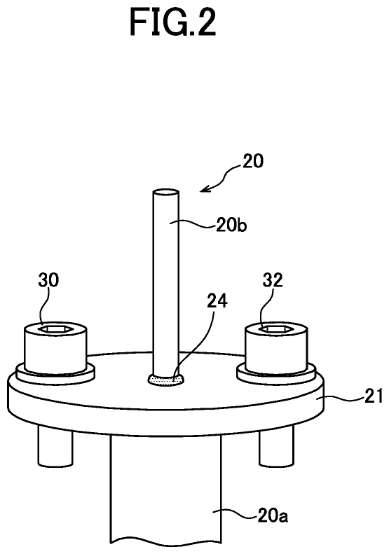

FIG. 2 is a diagram showing an example of a method of fixing the flange 21 to the lamp heater 20. In this example, the flange 21 is fixed to the lamp heater 20 by an adhesive 24. Specifically, the lamp heater 20 is fixed to the flange 21 by passing the power supply cord 20b through a central hole of the flange 21 and filling the central hole with the adhesive 24. The adhesive 24 secures the lamp heater 20 to the flange 21 and fills the central hole of the flange 21. According to one example, the adhesive 24 is an adhesive for vacuum sealing. The adhesive for vacuum sealing has excellent thermal insulation, oxidation resistance and chemical stability. In addition, the adhesive for vacuum sealing is an adhesive from which volatile matter has been removed.

According to one example, the flange 21 is provided with two holes for inserting two screws 30, 32. By tightening the screws 30, 32 into threaded holes in the chamber 12, the flange 21 and the lamp heater 20 may be fixed to the chamber 12.

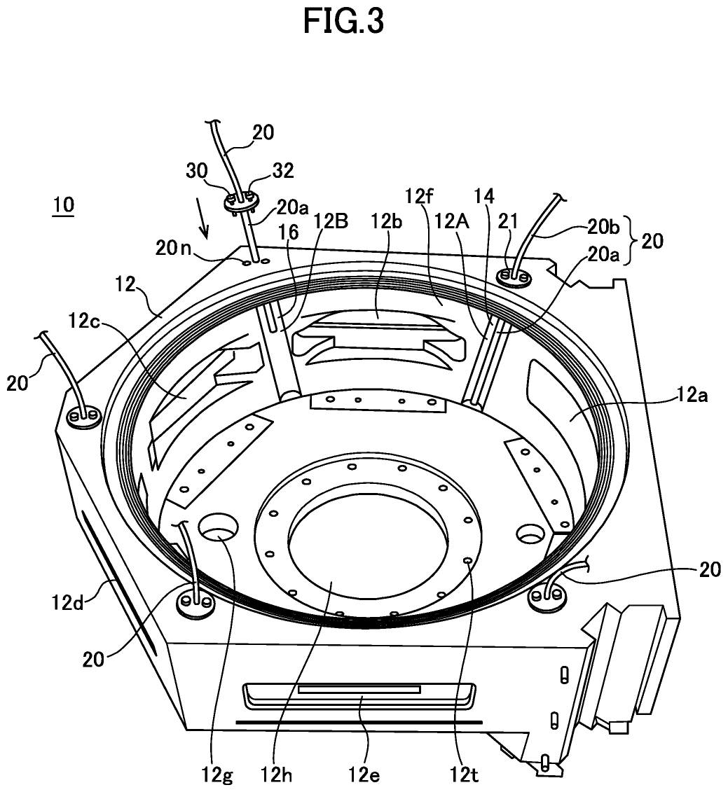

FIG. 3 is a diagram showing a method of attaching the lamp heater 20 to the chamber 12. For example, the lamp heater 20 integrated with the flange 21 in the manner described above is inserted into a hole of the chamber 12 in the direction of an arrow in FIG. 3. As a result, the light emitting portion 20a is housed in the concave part 12B. Then, by tightening the screws 30, 32 to threaded holes 12n of the chamber 12, the flange 21 is attached to the chamber 12. If the lamp heater 20 is deteriorated or the replacement time of the lamp heater 20 has arrived, the screws 30 and 32 may be removed, and the spent flange 21 and the lamp heater 20 may be taken out, to secure a new lamp heater and a new flange to the chamber 12.

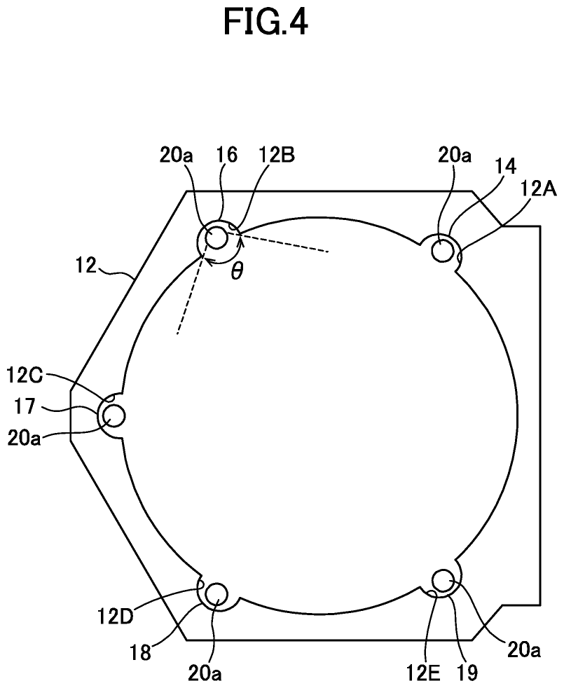

FIG. 4 is a cross-sectional view of the chamber 12 and the light emitting portions 20a.

The concave parts 12A, 12B, 12C, 12D, 12E are provided in the inner wall side surface of the chamber 12. Inner walls of the concave parts 12A, 12B, 12C, 12D, 12E are reflecting surfaces 14, 16, 17, 18, 19, respectively.

In this example, each light emitting portion 20a is disposed in the concave part.

An angle θ represents a spread angle of light emitted from the light emitting portion 20a.

In the example of FIG. 4, to heat an entire inner wall of the chamber 12 with the light emitted from the five light emitting portions 20a, the angle θ is set to, for example, 90° or more. When the number of the light emitting portions 20a is less than five, the angle θ is set to be greater than 90°, whereby the entire inner wall of the chamber 12 can be heated by light. On the other hand, if the number of the light emitting portions 20a is larger than five, the entire inner wall of the chamber 12 can be heated by light even if the angle θ is smaller than 90°.

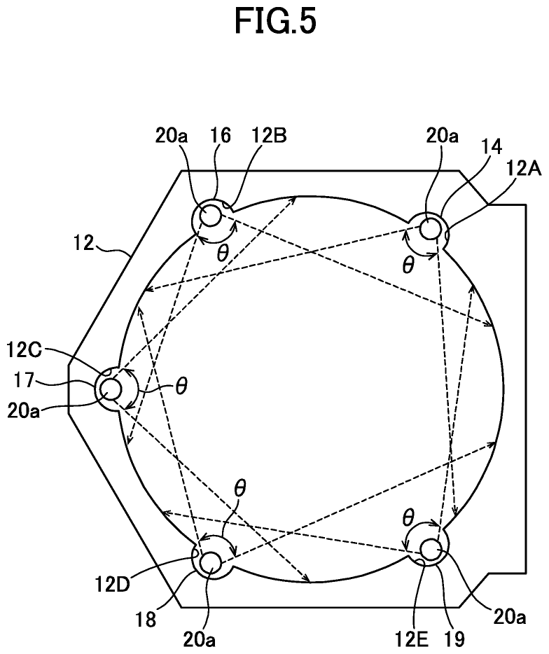

FIG. 5 is a diagram showing a spread of light by broken lines. In the example of FIG. 5, the entire inner wall of the chamber 12 can be heated by the light emitted from the light emitting portions 20a. According to one example, the entire inner wall includes the inner wall side surface, an inner wall upper surface and an inner wall lower surface.

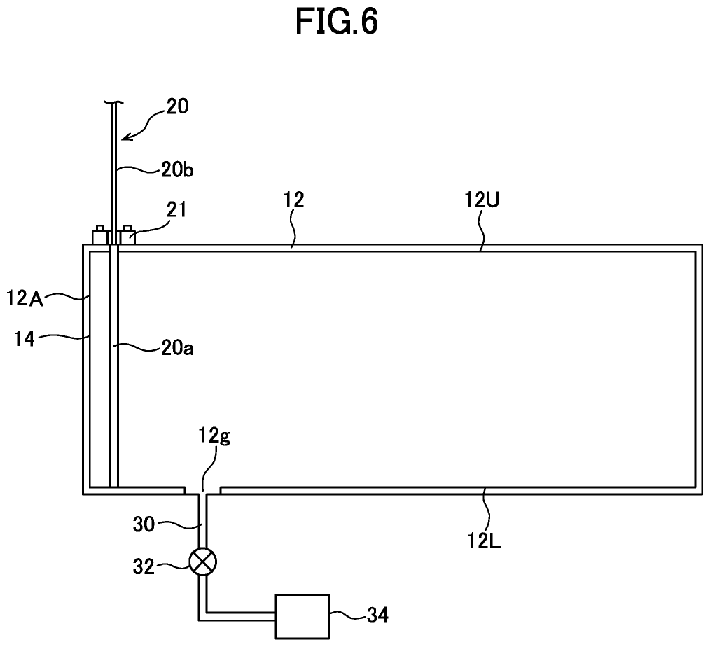

FIG. 6 is a longitudinal sectional view of the chamber 12 and the lamp heater 20.

The chamber 12 includes the inner wall upper surface 12U and the inner wall lower surface 12L. According to one example, the inner wall upper surface 12U is a part of the lid.

In the example of FIG. 6, a lower end of the light emitting portion 20a is substantially the same height as the inner wall lower surface 12L, and an upper end of the light emitting portion 20a is substantially the same height as the inner wall upper surface 12U.

According to one example, all the light emitting portions 20a are disposed as shown in FIG. 6. Equalizing a length of the light emitting portion 20a to a height of the interior space of the chamber 12 facilitate heating of the entire inner wall of the chamber 12.

According to another example, the length of the light emitting portion 20a may be smaller than the height of the interior space of the chamber 12.

FIG. 6 further shows that an exhaust pipe 30 is attached to the exhaust port 12g.

According to one example, a valve 32 for opening and closing a flow path of the exhaust pipe 30 is attached in a middle of the exhaust pipe 30. Furthermore, a vacuum pump 34 is connected to the exhaust pipe 30. With the valve 32 in the open state, the vacuum pump 34 can be operated to enhance the degree of vacuum in the chamber 12.

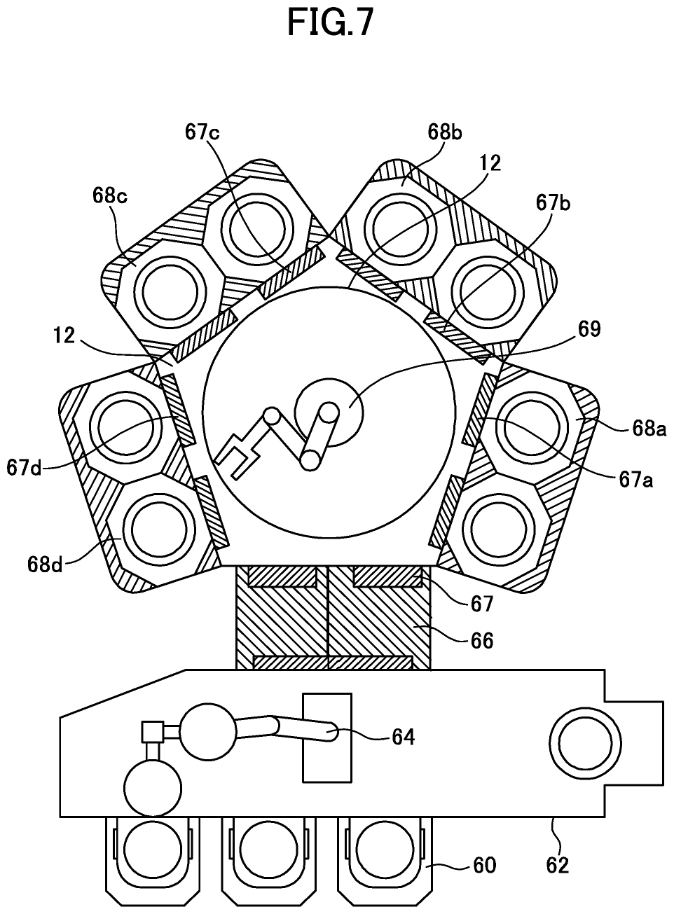

FIG. 7 is a diagram showing an example of a substrate processing apparatus including the substrate transfer system 10. The substrate processing apparatus includes a Load Port (LP) 60 on which a SMIF or a FOUP for storing wafers is mounted or opened or closed. An Equipment Front End Module (EFEM) 62 is connected to the LP 60. According to one example, in the EFEM 62, N2 gas or the like flows from above to below as downflow gas. A Load Lock Chamber (LLC) 66 is connected to the EFEM 62. The LLC 66 is used at atmospheric pressure when spatially connected to the EFEM 62 and vacuums when spatially connected to the chamber 12. The EFEM 62 described above is an interface between the LP60 and the LLC66. A substrate transfer robot 64 is provided in the EFEM 62 for transferring wafers between the LP 60 and the LLC 66.

Reactor chambers (RC) 68a are connected to one side surface of the chamber 12.

RCs 68b, 68c, 68d are connected to three other sides of the chamber 12, respectively. The reactor chambers 68a, 68b, 68c, 68d are chambers for performing film formation, etching, or film modification on a substrate. Gate valves (GV) 67a, 67b, 67c, 67d are respectively provided between the RC 68a, 68b, 68c, 68d and the chamber 12. By opening the GVs 67a, 67b, 67c, 67d, the RCs 68a, 68b, 68c, 68d and the chamber 12 are spatially connected. By closing the GVs 67a, 67b, 67c, 67d, the RCs 68a, 68b, 68c, 68d and the chamber 12 are spatially separated. Additionally, a gate valve 67 is provided between the chamber 12 and the LLC 66 to connect or break space in the LLC66 and space in the chamber 12.

The substrate transfer device 69 is provided in the chamber 12. The substrate transfer device 69 is, for example, a robot having at least one arm capable of moving with a plurality of joints. The number of arms may be plural. The substrate transfer device 69 is responsible for the transport of the substrate between LLC 66 and RC 68a, 68b, 68c, 68d.

The substrate processing apparatus of FIG. 7 is an example. According to another example, a module called Quad Chamber Module (QCM) with four reactor chambers may be attached to a side of the chamber 12.

Next, an example of a chamber purge method using the substrate transfer system 10 will be described. According to one example, purging in the chamber 12 with the lamp heaters 20 is performed as an initial exhaust. The initial exhaust is to evacuate unwanted gases in the chamber prior to transporting the substrates. In this example, by warming the entire inner wall of the chamber 12 and the substrate transfer device 69 with the lamp heaters 20, moisture adhering to the inner wall and the substrate transfer device 69 is removed. The entire inner wall of the chamber 12 and the substrate transfer device 69 are heated directly by the lamp heaters 20 in the chamber 12. According to one example, the surface temperature of the inner wall and the substrate transfer device 69 is increased to about 80° C. due to this heating.

Because there are light emitting portions 20a in the chamber 12, the entire inner wall of the chamber 12 and the substrate transfer device 69 quickly reach high temperatures. According to one example, it takes about three hours to allow the entire chamber 12 to reach the moisture stripping temperature if heaters are disposed in an outer surface of the chamber 12 or embedded in the chamber 12. In contrast, in the substrate transfer system 10, the light emitting portions 20a are provided in the chamber 12 so that the inner wall of the chamber 12 and the substrate transfer device 69 can be directly heated. In this case, the time required for the inner wall and the substrate transfer device 69 to reach the moisture stripping temperature is only about 3 minutes.

According to one example, heating of the inner wall and the substrate transfer device 69 is performed in a state in which all the through holes 12a, 12b, 12c, 12d, 12e of the chamber 12 are closed by the gate valves. When the lamp heaters 20 are energized to heat the inner wall and the substrate transfer device 69, water molecules adsorbed on the inner wall and the substrate transfer device 69 are peeled off from the inner wall and the substrate transfer device 69. Then the water molecules are pumped out of the chamber 12 by the vacuum pump 34. Thus, the amount of moisture in the chamber 12 is reduced.

Thereafter, stop the energization of the lamp heaters 20, open the gate valves, and start the transfer of the substrates by the substrate transfer device 69. When a series of substrate transfer processing is completed, the initial exhaust is performed again prior to subsequent substrate transfer processing. That is, close the gate valves again, and energize the lamp heaters 20 to discharge water molecules. Thus, the initial exhaust can be performed periodically. According to one example, no gas is supplied into the chamber 12 during the initial exhaust, and an inert gas, such as N2 gas, is supplied into the chamber 12 during transfer of the substrates. According to another example, the initial exhaust and substrates transfer are performed while inert gas is provided in the chamber 12. In one example, the vacuum pump 34 is operated both during the initial exhaust period and the substrate transfer period to reduce the pressure in the chamber 12.

Thus, the substrate transfer system 10 intensively heats the inner wall of the chamber 12 and the substrate transfer device 69 rather than the entire chamber 12. Therefore, moisture can be removed at high speed with less power consumption than in the case of heating the entire chamber 12.

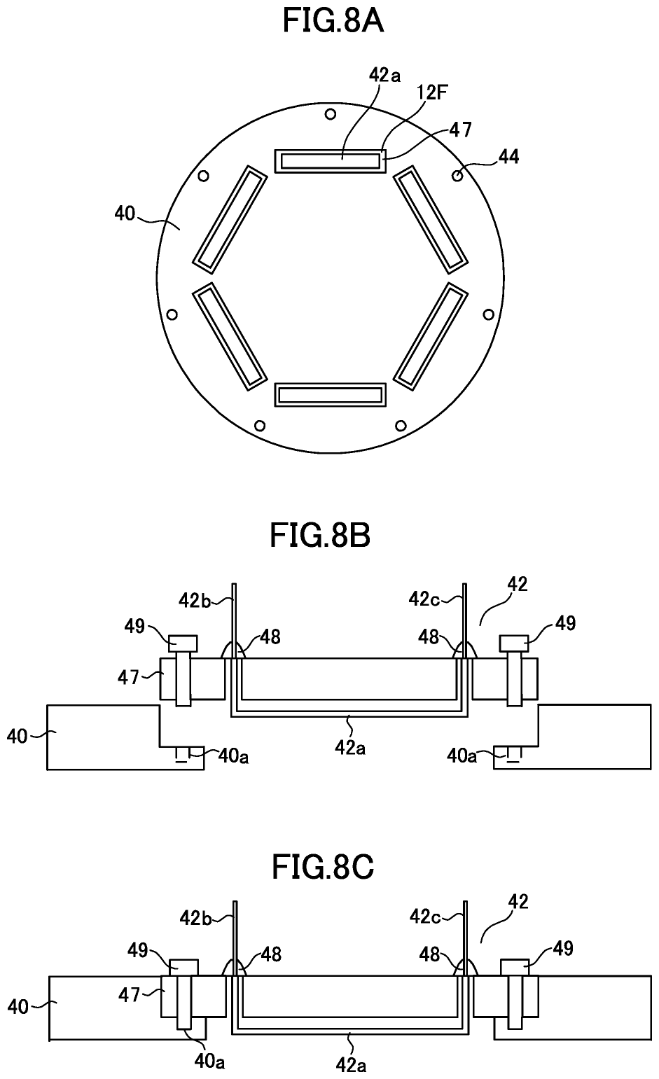

In the examples described above, the lamp heaters 20 are provided on the inner wall side surface of the chamber 12. However, the lamp heaters 20 may be provided at any location in the chamber 12. Referring to FIGS. 8-12, examples of attaching the lamp heaters in various positions will be described.

FIGS. 8A, 8B, 8C are diagrams showing exemplary lamp heaters provided on the lid 40 of the chamber 12. FIG. 8 A shows a bottom view of the lid 40. Concave parts 12F are formed in a bottom surface of the lid 40. In an example of FIG. 8A, six rectangular concave parts 12F are formed in the lid 40. According to one example, a light emitting portion 42a is housed in each of the concave parts 12F.

A plurality of holes 44 are formed along an outer edge of the lid 40. The lid 40 is secured to the chamber 12 by inserting screws into the holes 44 and screwing the screws into threaded holes in the chamber 12. Upon securing the lid 40 to the chamber 12, the light emitting portions 42a are located on the inner wall upper surface of the chamber 12. In each of the concave parts 12F, the light emitting portion 42a and a flange 47 are exposed.

FIG. 8B is a cross-sectional view of a portion of the lid 40 and an attachment to the lid 40. The attachment includes the lamp heater 42 and the flange 47. According to one example, the lamp heater 42 includes the light emitting portion 42a, and power supply codes 42b, 42c connected to both ends thereof. In this example, the flange 47 is fixed to the lamp heater 42 with two adhesives 48. Openings of the flange 47 are closed with the adhesives 48 to ensure airtightness in the chamber 12. In one example, screws 49 are passed through through-holes of the flange 70. Screw holes 40a of the lid 40 are provided immediately below the through-holes.

FIG. 8C is a cross-sectional view of the flange 47 secured to the lid 40. By screwing the screws 49 into the screw holes 40a, the flange 47 is fixed to the lid 40. As is apparent from FIG. 8C, the concave parts are provided by a lower surface of the flange 47 and a side surface of the lid 40. In one example, the lower surface of the flange 47 and the side surface of the lid 40 serve as the reflecting surface. In other words, an inner wall of the concave parts 12F are reflecting surface. The light emitting portion 42a is stably installed in the chamber 12 by fixing the lid 40 to the chamber 12.

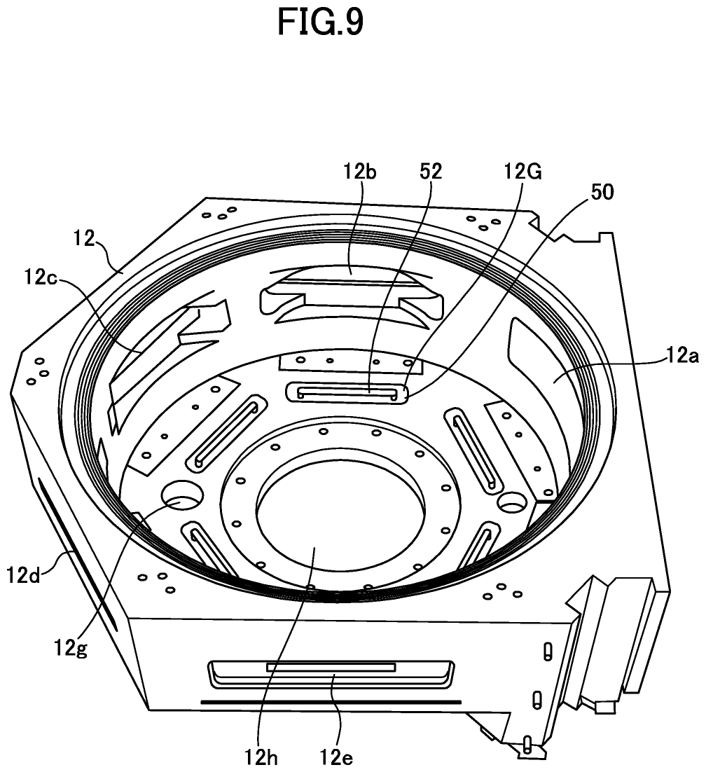

FIG. 9 is a diagram showing an example of providing lamp heaters on the inner wall lower surface of the chamber. Concave parts 12G are formed on the inner wall lower surface of the chamber 12. Reflecting surfaces 50 are provided as inner walls of the concave parts 12G. In each of the concave parts 12G, a light emitting portion of a lamp heater 52 is housed. A configuration of the lamp heaters 52 and a method of attaching the lamp heaters 52 to the chamber 12 may be the same as described with reference to FIGS. 8A, 8B, 8C. Light emitted from the light emitting portions of the lamp heaters 52 heats the inner wall and the substrate transfer device to exhaust moisture to the outside of the chamber 12.

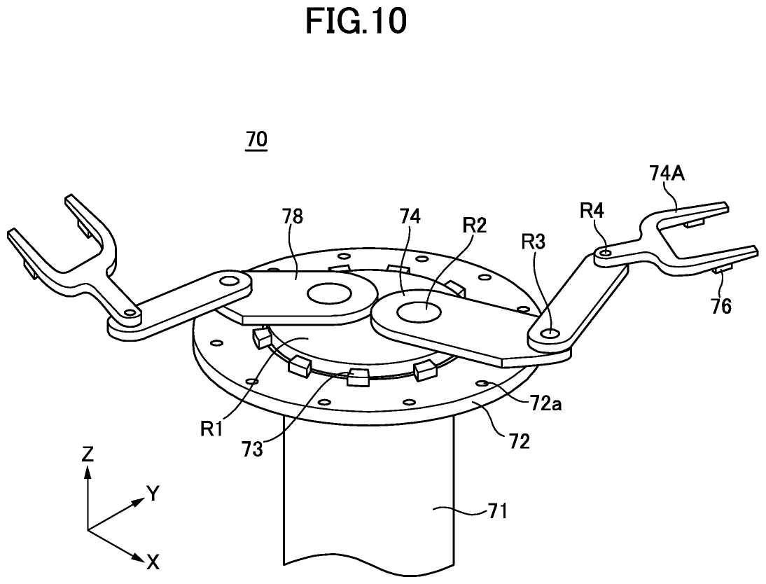

FIG. 10 is a diagram showing an example of attaching at least one lamp heater to a substrate transfer device 70. In one example, the substrate transfer device 70 includes a flange 72 having a plurality of holes 72a. By inserting screws into these holes 72a, and by turning the screws into the screw holes 12t in FIG. 1, it is possible to secure the substrate transfer device 70 to the chamber 12. The substrate transfer device 70 includes two arms 74, 78. Rotation of a rotation axis R1 displaces the arms 74, 78 in a rotation direction.

Further, the arm 74 has rotation axes R2, R3, R4. The arm 78 similarly includes three rotation axes. Therefore, the arms 74, 78 constitute a two-arm robot with four degrees of freedom. According to another example, degree of freedom of the arms can be increased or decreased, or the number of the arms can be increased or decreased.

At least one lamp heater is fixed to the substrate transfer device 70. According to an example, lamp heaters 73 are fixed to the rotation axis R1 of the substrate transfer device 70. Furthermore, lamp heaters 76 are fixed to an end effector 74A. Since an upper surface of the end effector 74A is a part for adsorbing or mounting the substrate, the lamp heaters 76 are provided on a lower surface of the end effector 74A.

According to one example, the lamp heaters 73 heat the inner wall of the chamber 12 and a part of the substrate transfer device 70 by emitting light primarily laterally and upwardly. The lamp heaters 76 heat the inner wall of the chamber 12 and a part of the substrate transfer device 70 by emitting light primarily in lateral and downward directions. According to another example, it is possible to omit the lamp heaters 73 or the lamp heaters 76.

The inner wall and the substrate transfer device 70 may be heated while changing a position of the lamp heaters 73, 76. As a result, water molecules can be efficiently discharged out of the chamber 12. For example, by energizing the lamp heaters 76 while moving the end effectors 74A along the inner wall surface of the chamber 12, it is possible to quickly heat the inner wall surface.

It is also possible to heat the inner wall of the chamber 12 substantially uniformly by energizing the lamp heaters 73 while rotating the rotation axis R1. According to another example, it is possible to energize the lamp heaters while stopping movement of the substrate transfer device 70.

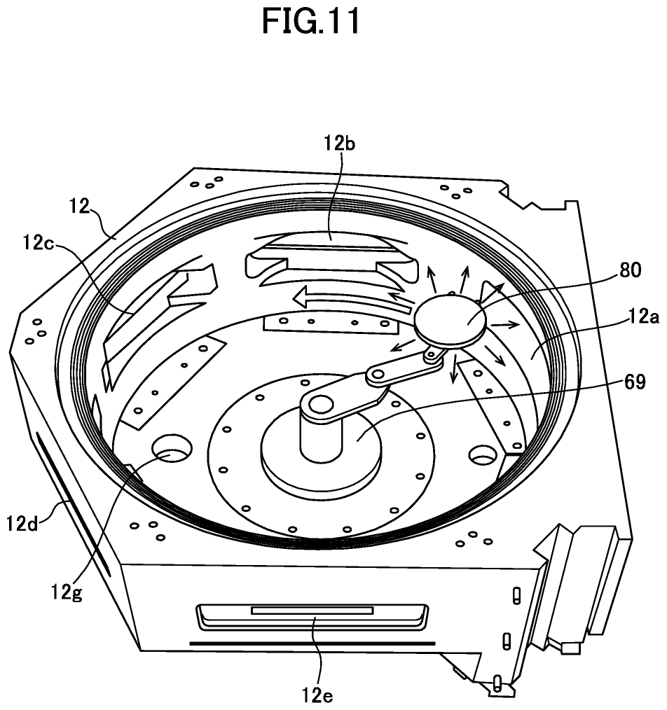

FIG. 11 is a diagram showing an example in which moisture is removed by a plate-like body 80 in which a lamp heater is housed. The plate-like body 80 can be carried by the substrate transfer device 69 in the same way as a product wafer. The plate-like body 80 has, for example, a shape substantially equivalents to that of a wafer. Thus, for example, by utilizing the substrate processing apparatus of FIG. 7, it is possible to carry the plate-like body 80 from LP 60 to the substrate transfer device 69 in the chamber 12.

The plate-like body 80 is configured to serve as a lamp heater. A certain area of the plate-like body 80 serves as a light-emitting portion. For example, an upper surface and a side surface of the plate-like body 80 are light-emitting portions. According to one example, the plate-like body 80 includes at least one lamp heater that is covered with a transparent box. According to another example, the at least one lamp heater is not covered and is exposed to the outside.

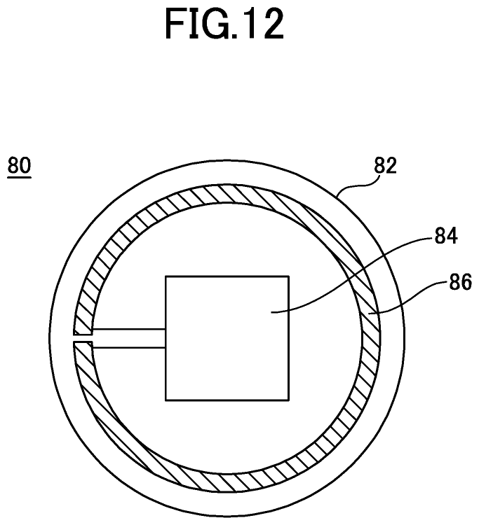

FIG. 12 is a diagram showing a configuration example of the plate-like body 80. The plate-like body 80 includes a lamp heater 86, and a battery 84 for supplying power to the lamp heater 86. According to one example, the lamp heater 86 is provided annularly in a plan view. The lamp heater 86 fed from the battery 84 emits light to heat objects around the plate-like body 80.

Thin arrows shown in FIG. 11 represent light generated from the plate-like body 80.

The bold arrow in FIG. 11 is an arrow along the inner wall side surface of the chamber 12.

By causing the plate-like body 80 to emit light while moving the end effector in the direction of the bold arrow, the inner wall side surface of the chamber 12 can be successively heated.

When the plate-like body 80 emits light, the entire inner wall of the chamber 12 may be heated. But the temperature is particularly increased in a portion where the plate-like body 80 and the inner wall surface are close to each other, so that moisture can be efficiently removed.

According to another example, the plate-like body 80 may be positioned at or near the center of the space of the chamber 12, and the entire inner wall may be collectively heated while movement of the substrate transfer device 69 is stopped.

Although the substrate transfer device 69 has a single arm, it may be used a substrate transfer device having a plurality of arms. In this case, by holding a plurality of plate-like bodies by the plurality of arms and causing the plurality of plate-like bodies to emit light, it is possible to further improve the efficiency of moisture removal. After the moisture is substantially removed, the plate-like body 80 can be transported to the LP 60 in the same procedure as the procedure of retracting the wafer to the LP 60.

Many modifications and variations of the present disclosure are possible in the light of the above teachings.

1. A substrate transfer system comprising:
a chamber in which a plurality of through holes are formed on a side surface;
a substrate transfer device provided in the chamber; and
a lamp heater disposed in the chamber.

2. The substrate transfer system according to claim 1, wherein
a concave part is formed on an inner wall of the chamber, and
the lamp heater is disposed in the concave part.

3. The substrate transfer system according to claim 2, wherein a wall surface of the concave part is a reflecting surface that reflects light.

4. The substrate transfer system according to claim 1, comprising a flange fixed with an adhesive to the lamp heater, the flange is screwed to the chamber.

5. The substrate transfer system according to claim 1, wherein the lamp heater is provided on an inner wall side surface of the chamber.

6. The substrate transfer system according to claim 5, comprising a plurality of the lamp heaters provided at substantially equal intervals in a plan view on the inner wall side surface.

7. The substrate transfer system according to claim 5, wherein
a lower end of a light emitting portion of the lamp heater is substantially the same height as an inner wall lower surface of the chamber, and
an upper end of the light emitting portion is substantially the same height as an inner wall upper surface of the chamber.

8. The substrate transfer system according to claim 1, wherein the lamp heater is provided on an inner wall upper surface of the chamber.

9. The substrate transfer system according to claim 1, wherein the lamp heater is provided on an inner wall lower surface of the chamber.

10. The substrate transfer system according to claim 1, wherein the lamp heater is fixed to the substrate transfer device.

11. The substrate transfer system according to claim 10, wherein the lamp heater is fixed to a rotation axis of the substrate transfer device.

12. The substrate transfer system according to claim 10, wherein
the substrate transfer device includes an end effector, and
the lamp heater is secured to the end effector.

13. A chamber purge method comprising:
causing a lamp heater provided in a chamber to emit light to remove water molecules adsorbed to both an inner wall of the chamber and a substrate transfer device provided in the chamber; and
discharging the water molecules out of the chamber.

14. The chamber purge method according to claim 13, wherein
the lamp heater is fixed to the substrate transfer device, and
the water molecules adsorbed to both the inner wall and the substrate transfer device are removed while changing a position of the lamp heater by driving the substrate transfer device.

15. The chamber purge method according to claim 14, wherein the lamp heater is secured to a rotation axis of the substrate transfer device.

16. The chamber purge method according to claim 14, wherein the lamp heater is secured to an end effector of the substrate transfer device.

17. The chamber purge method according to claim 13, wherein the lamp heater is a plate-like body that can be transferred by the substrate transfer device.

18. The chamber purge method according to claim 17, wherein the lamp heater emits light by a battery disposed in the plate-like body.
